(19) United States
(12) Patent Application Publication
(10) Pub. No.: US 2012/0180860 A1
(43) Pub. Date: Jul. 19, 2012

(54) SOLAR CELL AND METHOD FOR MANUFACTURING THE SAME

(76) Inventors: Jihoon Ko, Seoul (KR); Jinho Kim, Seoul (KR); Junyong Ahn, Seoul (KR); Daeyong Lee, Seoul (KR)

(21) Appl. No.: 13/343,927

(22) Filed: Jan. 5, 2012

(30) Foreign Application Priority Data
Jan. 14, 2011 (KR) 10-2011-0004079

(51) Int. Cl. H01L 31/0216; H01L 31/0236; H01L 31/02; H01L 31/18

(52) U.S. Cl. 136/256; 438/72; 438/71; 136/252; 257/E31.119; 257/E31.13

(57) ABSTRACT

A solar cell and a method for manufacturing the same are disclosed. The method for manufacturing the solar cell includes forming an emitter region of a second conductive type opposite a first conductive type at a first surface of a substrate of the first conductive type by using an ion implantation method, forming a passivation layer on a second surface positioned opposite the first surface of the substrate, and forming a first electrode, which is positioned on the first surface of the substrate and is connected to the emitter region, and a second electrode, which is positioned on the second surface of the substrate and is selectively connected to the substrate through the passivation layer.

This application claims priority to and the benefit of Korean Patent Application No. 10-2011-0004079, filed in the Korean Intellectual Property Office on Jan. 14, 2011, the entire content of which is incorporated herein by reference.

### BACKGROUND OF THE INVENTION

1. Field of the Invention

Embodiments of the invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts, which have different conductive types, for example, a p-type and an n-type, and form a p-n junction, and electrodes respectively connected to the semiconductor parts of the different conductive types.

When light is incident on the solar cell, electron-hole pairs are generated in the semiconductor parts. The electrons and the holes move under the influence of the p-n junction to the n-type semiconductor part and the p-type semiconductor part, respectively. The electrons and the holes are collected by the electrodes connected to the n-type semiconductor part and the p-type semiconductor part, respectively. The electrodes are connected to each other using electric wires to thereby obtain electric power.

### SUMMARY OF THE INVENTION

In one aspect, there is a method for manufacturing a solar cell including forming an emitter region of a second conductive type opposite a first conductive type at a first surface of a substrate of the first conductive type by using an ion implantation method, forming a passivation layer on a second surface positioned opposite the first surface of the substrate, and forming a first electrode, which is positioned on the first surface of the substrate and is connected to the emitter region, and a second electrode, which is positioned on the second surface of the substrate and is selectively connected to the substrate through the passivation layer.

The forming of the emitter region may include implanting impurities of the second conductive type into the first surface of the substrate using the ion implantation method to form an impurity region at the first surface of the substrate, and performing a thermal process on the substrate having the impurity region in an atmosphere of oxygen to convert the impurity region into the emitter region and to form first and second thermal oxide films on the first and second surfaces of the substrate.

The thermal process may be performed at a temperature of substantially 700° C. to 900° C.

The method may further include removing the first and second thermal oxide films.

The passivation layer may be formed on the second thermal oxide film positioned on the second surface of the substrate.

The method may further include forming an anti-reflection layer on the first thermal oxide film positioned on the first surface of the substrate.

The first electrode may be connected to the substrate through the anti-reflection layer and the first thermal oxide film.

The anti-reflection layer may be formed of silicon nitride.

Each of the first and second thermal oxide films may have a thickness of substantially 15 nm to 30 nm.

The method may further include forming an anti-reflection layer on the emitter region,

The first electrode may be connected to the emitter region through the anti-reflection layer.

The passivation layer may be formed of silicon nitride.

The forming of the passivation layer may include forming a first passivation layer using silicon oxide, and forming a second passivation layer using silicon nitride.

The forming of the passivation layer may include forming a first passivation layer using aluminum oxide, and forming a second passivation layer using silicon nitride.

The first conductive type may be of a p-type, and the second conductive type may be of an n-type. Alternatively, the first conductive type may be of an n-type, and the second conductive type may be of a p-type.

The method may further include, before forming the emitter region, forming a textured surface on each of the first and second surfaces of the substrate.

The method may further include polishing the textured surface formed on the second surface of the substrate to form a flat surface.

In another aspect, there is a solar cell including a substrate of a first conductive type, the substrate including first and second surfaces, which are positioned opposite each other, an emitter region of a second conductive type opposite the first conductive type, which is formed at the first surface of the substrate using an ion implantation method, a first electrode which is positioned on the first surface of the substrate and is electrically connected to the emitter region, a passivation layer positioned on the second surface of the substrate, and a second electrode which is positioned on the second surface of the substrate and is selectively connected to the substrate through the passivation layer.

The emitter region may have a sheet resistance of substantially 60 Ω/sq. to 120 Ω/sq.

The solar cell may further include a first thermal oxide film positioned on the emitter region and a second thermal oxide film positioned on the second surface of the substrate. The passivation layer may be positioned on the second thermal oxide film. The first electrode may be connected to the emitter region through the first thermal oxide film, and the second electrode may be connected to the substrate through the passivation layer and the second thermal oxide film.

Each of the first and second thermal oxide films may have a thickness of substantially 15 nm to 30 nm.

The passivation layer may be formed of silicon nitride.

The passivation layer may have a thickness of substantially 40 nm to 80 nm.

The solar cell may further include an anti-reflection layer positioned on the first thermal oxide film. The anti-reflection layer may be formed of silicon nitride.

The solar cell may further include an anti-reflection layer positioned on the emitter region. The first electrode may pass through the anti-reflection layer and may contact the emitter region. The anti-reflection layer may be formed of silicon nitride.

The passivation layer may include a first passivation layer, which is positioned on the second surface of the substrate and is formed of silicon oxide, and a second passivation layer, which is positioned on the first passivation layer and is formed of silicon nitride. In this instance, the first passivation layer may have a thickness of substantially 200 nm to 300 nm, and the second passivation layer may have a thickness of substantially 40 nm to 80 nm.

The passivation layer may include a first passivation layer, which is positioned on the second surface of the substrate and is formed of aluminum oxide, and a second passivation layer, which is positioned on the first passivation layer and is formed of silicon nitride. In this instance, the first passivation layer may have a thickness of substantially 30 nm to 70 nm, and the second passivation layer may have a thickness of substantially 40 nm to 80 nm.

The solar cell may further include a field region, which adjoins the second electrode and is positioned at the substrate.

Roughnesses of the first and second surfaces of the substrate may be substantially equal to each other. Roughnesses of the first and second surfaces of the substrate may be different from each other.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial perspective view of a solar cell according to an example embodiment of the invention;

FIG. 2 is a cross-sectional view taken along line II-II of FIG. 1;

FIGS. 3A to 3J sequentially illustrate a method for manufacturing a solar cell according to an example embodiment of the invention;

FIG. 4 is a partial perspective view of a solar cell according to another example embodiment of the invention;

FIG. 5 is a cross-sectional view taken along line V-V of FIG. 4; and

FIGS. 6A to 6G sequentially illustrate a method for manufacturing a solar cell according to another example embodiment of the invention.

### DETAILED DESCRIPTION OF THE EMBODIMENTS

Embodiments of the invention will be described more fully hereinafter with reference to the accompanying drawings, in which example embodiments of the invention are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

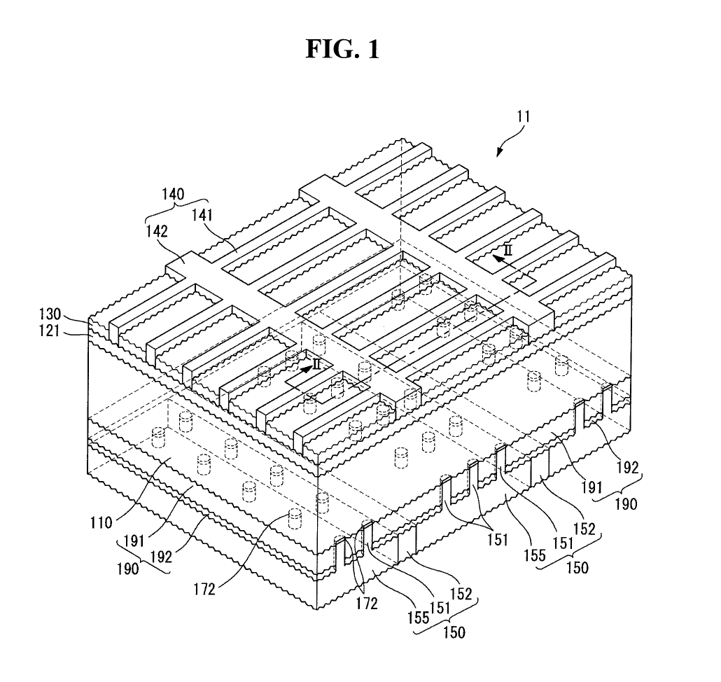

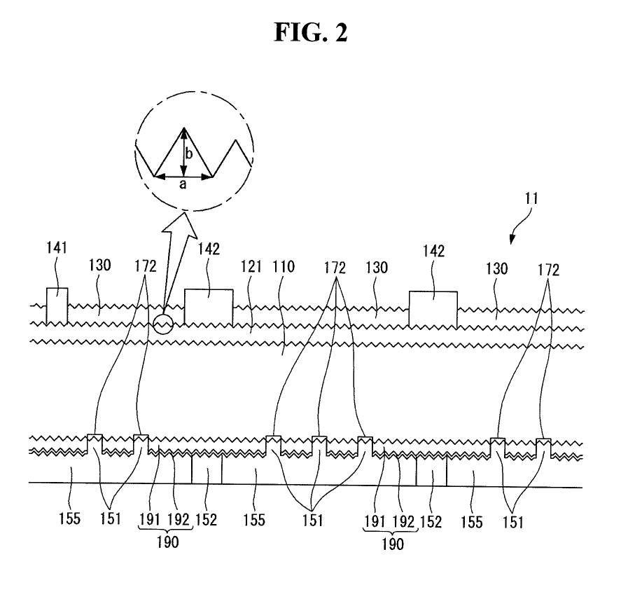

A solar cell according to an example embodiment of the invention is described below with reference to FIGS. 1 and 2.

As shown in FIG. 1, a solar cell 11 according to an example embodiment of the invention includes a substrate 110, an emitter region 121 positioned at an incident surface (hereinafter, referred to as “a front surface or a first surface”) of the substrate 110 on which light is incident, an anti-reflection layer 130 positioned on the emitter region 121, a front electrode part (or a first electrode part) 140 connected to the emitter region 121, a passivation layer 190 positioned on a surface (hereinafter, referred to as “a back surface or a second surface”) opposite the front surface of the substrate 110, a back electrode part (or a second electrode part) 150 which is positioned on the passivation layer 190 and is connected to the substrate 110, and a plurality of field regions (i.e., back surface field (BSF) regions) 172 which are selectively positioned at the back surface of the substrate 110.

The substrate 110 is a semiconductor substrate formed of a semiconductor such as first conductive type silicon, for example, p-type silicon, though not required. The semiconductor is crystalline semiconductor, such as single crystal silicon or polycrystalline silicon.

When the substrate 110 is of the p-type, the substrate 110 may be doped with impurities of a group III element such as boron (B), gallium (Ga), and indium (In). Alternatively, the substrate 110 may be of an n-type, and may be formed of a semiconductor material other than silicon. When the substrate 110 is of the n-type, the substrate 110 may be doped with impurities of a group V element such as phosphorus (P), arsenic (As), and antimony (Sb).

As shown in FIGS. 1 and 2, a texturing process is independently performed on the front surface and the back surface of the substrate 110, and thus, the front surface and the back surface of the substrate 110 each have a textured surface corresponding to an uneven surface having a plurality of projections and a plurality of depressions or having uneven characteristics. In this instance, the emitter region 121 and the anti-reflection layer 130 positioned on the front surface of the substrate 110, and the passivation layer 190 and the back electrode part 150 positioned on the back surface of the substrate 110 each have the textured surface.

As described above, because the front surface of the substrate 110 is textured, an incident area of the substrate 110 increases and a light reflectance decreases due to a plurality of reflection operations resulting from the textured surface. Hence, an amount of light incident on the substrate 110 increases, and the efficiency of the solar cell 11 is improved. In addition, because the back surface of the substrate 110 is textured, an amount of light, which passes through the substrate 110 and is again reflected on the substrate 110, increases by the textured back surface of the substrate 110. Hence, an amount of light again incident on the substrate 110 from the textured back surface of the substrate 110 increases. All of the projections of the textured surface of the substrate 110 shown in FIGS. 1 and 2 equally have a maximum diameter “a” and a maximum height “b” for the sake of convenience. However, because the maximum diameters “a” and the maximum heights “b” of the projections are determined to be non-uniform, the projections actually have the different maximum diameters “a” and the different maximum heights “b”.

In the embodiment of the invention, the maximum diameter “a” and the maximum height “b” of each of the projections formed on the front surface and the back surface of the substrate 110 may be approximately 5 μm to 15 μm. Further, an aspect ratio “b/a” of each projection may be approximately 0.2 to 2.

Because each of the front surface and the back surface of the substrate 110 forms the textured surface through use of one process, the front surface and the back surface of the substrate 110 are substantially the same as each other in a roughness per unit area of the textured surface.

However, because the front surface and the back surface of the substrate 110 are different from each other in the surface state, the surface size exposed by an etching material, etc., the roughness of the textured front surface of the substrate 110 may be different from the roughness of the textured back surface of the substrate 110.

Unlike the embodiment of the invention, the back surface of the substrate 110 may have not the textured surface but a flat surface. In this instance, the textured back surface of the substrate 110 may be transformed into the flat surface through a separate process, for example, a polishing process.

The emitter region 121 is a region doped with impurities of a second conductive type (for example, n-type) opposite the first conductive type (for example, p-type) of the substrate 110. Thus, the emitter region 121 of the second conductive type forms a p-n junction along with a first conductive type region of the substrate 110.

A plurality of electron-hole pairs produced by light incident on the substrate 110 are separated into electrons and holes by a built-in potential difference resulting from the p-n junction between the substrate 110 and the emitter region 121. Then, the electrons move to the n-type semiconductor, and the holes move to the p-type semiconductor. Thus, when the substrate 110 is of the p-type and the emitter region 121 is of the n-type, the holes move to the substrate 110 and the electrons move to the emitter region 121.

Because the emitter region 121 forms the p-n junction along with the substrate 110, the emitter region 121 may be of the p-type when the substrate 110 is of the n-type, in another embodiment of the invention. In this instance, the electrons move to the substrate 110 and the holes move to the emitter region 121.

Returning to the embodiment of the invention, when the emitter region 121 is of the n-type, the emitter region 121 is formed by doping the substrate 110 with impurities of a group V element using, for example, an ion implantation method. On the contrary, when the emitter region 121 is of the p-type, the emitter region 121 is formed by doping the substrate 110 with impurities of a group III element using the ion implantation method. As above, when the emitter region 121 is formed using the ion implantation method, the emitter region 121 is formed only at one surface (for example, the front surface) of the substrate 110. In the ion implantation method, a doping amount of impurities (i.e., an implantation amount of ions) implanted into the substrate 110 and a doping depth (i.e., an ion implantation depth) of impurities vary depending on a production amount of ions, a velocity of ions moving to the substrate 110, etc. Further, the production amount of ions and the ion velocity are easily controlled using electric power applied in an ion implantation process, etc. Thus, an amount of impurities implanted into the substrate 110 and the impurity doping depth when the emitter region 121 is formed using the ion implantation method are controlled more easily than those when the emitter region 121 is formed by doping the substrate 110 with impurities using a thermal diffusion method.

For example, ion implantation energy may be approximately 100 KeV to 3 MeV, and the impurity doping depth based on the ion implantation energy may be approximately 0.5 μm to 10 μm measured from the surface of the substrate 110.

Because the ion implantation amount and the ion implantation depth are more easily controlled, the emitter region 121 has a sheet resistance of about 60 Ω/sq. to 120 Ω/sq., which is greater than a sheet resistance when the emitter region 121 is formed using the thermal diffusion method. Hence, an impurity doping concentration of the emitter region 121 in the ion implantation method is lower than an impurity doping concentration of the emitter region 121 in the thermal diffusion method. Further, because the impurity doping depth of the emitter region 121 in the ion implantation method is less than the impurity doping depth of the emitter region 121 in the thermal diffusion method, an amount of carriers lost by impurities greatly decreases.

When the sheet resistance of the emitter region 121 is equal to or greater than about 60 Ω/sq., an amount of light absorbed in the solar cell 11 decreases by the emitter region 121. Hence, a reduction in an amount of light incident on the substrate 110 decreases, and an amount of carriers lost by impurities existing in the emitter region 121 further decreases.

When the sheet resistance of the emitter region 121 is equal to or less than about 120 Ω/sq., the emitter region 121 stably forms the p-n junction along with the substrate 110. Hence, electrons and holes are more stably produced, and a shunt error, in which the front electrode part 140 passes through the emitter region 121 and contacts the substrate 110, is prevented.

The anti-reflection layer 130 positioned on the emitter region 121 having the textured surface reduces a reflectance of light incident on the solar cell 11 and increases selectivity of a predetermined wavelength band, thereby increasing the efficiency of the solar cell 11.

The anti-reflection layer 130 may be formed of transparent hydrogenated silicon nitride (SiNx:H). The anti-reflection layer 130 may have a thickness of about 70 nm to 80 nm and a refractive index of about 2.0 to 2.1.

When the refractive index of the anti-reflection layer 130 is equal to or greater than about 2.0, the reflectance of light decreases and an amount of light absorbed in the anti-reflection layer 130 further decreases. Further, when the refractive index of the anti-reflection layer 130 is equal to or less than about 2.1, the reflectance of the anti-reflection layer 130 further decreases.

Further, in the embodiment of the invention, the anti-reflection layer 130 has the refractive index of about 2.0 to 2.1 between a refractive index (about 1) of air and a refractive index (about 3.5) of the substrate 110. Thus, because a refractive index in going from air to the substrate 110 gradually increases, the reflectance of light further decreases by the gradual increase in the refractive index. As a result, an amount of light incident on the substrate 110 further increases.

When the thickness of the anti-reflection layer 130 is equal to or greater than about 70 nm, an anti-reflection effect of light is more efficiently obtained. When the thickness of the anti-reflection layer 130 is equal to or less than about 80 nm, an amount of light absorbed in the anti-reflection layer 130 decreases and an amount of light incident on the substrate 110 increases. Further, in the process for manufacturing the solar cell 11, the front electrode part 140 easily and smoothly passes through the anti-reflection layer 130 and is stably and smoothly connected to the emitter region 121.

By hydrogen (H) contained in the anti-reflection layer 130, the anti-reflection layer 130 performs a passivation function which converts a defect, for example, dangling bonds existing at and around the surface of the substrate 110 into stable bonds using hydrogen (H) contained in the anti-reflection layer 130 to thereby prevent or reduce a recombination and/or a disappearance of carriers moving to the surface of the substrate 110. As a result, the anti-reflection layer 130 reduces an amount of carriers lost by the defect at the surface of the substrate 110.

The anti-reflection layer 130 shown in FIGS. 1 and 2 has a single-layered structure, but may have a multi-layered structure, for example, a double-layered structure. Further, the anti-reflection layer 130 may be omitted, if necessary or desired.

The front electrode part 140 includes a plurality of front electrodes (or a plurality of first electrodes) 141 and a plurality of front bus bars (or a plurality of first bus bars) 142 connected to the plurality of front electrodes 141.

The plurality of front electrodes 141 are connected to the emitter region 121, are spaced apart from one another at a distance therebetween, and extend parallel to one another in a fixed direction. The plurality of front electrodes 141 collect carriers (for example, electrons) moving to the emitter region 121

The plurality of front bus bars 142 are connected to the emitter region 121 and extend parallel to one another in a direction crossing the front electrodes 141.

In this instance, the front bus bars 142 are positioned at the same layer level as the front electrodes 141 and are electrically and physically connected to the front electrodes 141 at crossings of the front electrodes 141 and the front bus bars 142.

Accordingly, as shown in FIG. 1, the plurality of front electrodes 141 have a stripe shape extending in a transverse (or longitudinal) direction, and the plurality of front bus bars 142 have a stripe shape extending in a longitudinal (or transverse) direction. Hence, the front electrode part 140 has a lattice shape on the front surface of the substrate 110.

The front bus bars 142 collect not only carriers (for example, electrons) moving from the emitter region 121 but also carriers collected by the front electrodes 141 crossing the front bus bars 142, and move the collected carriers in a desired direction. Thus, a width of each front bus bar 142 is greater than a width of each front electrode 141.

The plurality of front bus bars 142 are connected to an external device and output the collected carriers to the external device.

The front electrode part 140 including the front electrodes 141 and the front bus bars 142 is formed of at least one conductive material such as silver (Ag). Alternatively, the conductive material may be at least one selected from the group consisting of nickel (Ni), copper (Cu), aluminum (Al), tin (Sn), zinc (Zn), indium (In), titanium (Ti), gold (Au), and a combination thereof. Other conductive materials may be used.

In the embodiment of the invention, the number of front electrodes 141 and the number of front bus bars 142 may vary, if necessary.

The passivation layer 190 positioned on the textured back surface of the substrate 110 includes a first passivation layer 191 positioned on the textured back surface of the substrate 110 and a second passivation layer 192 positioned on the first passivation layer 191.

The first passivation layer 191 may be formed of silicon oxide (SiOx) or aluminum oxide (AlxOy). Other materials may be used. When the first passivation layer 191 is formed of silicon oxide (SiOx), the first passivation layer 191 may have a thickness of about 200 nm to 300 nm. When the first passivation layer 191 is formed of aluminum oxide (AlxOy), the first passivation layer 191 may have a thickness of about 30 nm to 70 nm.

The second passivation layer 192 may be formed of silicon nitride (SiNx) and may have a thickness of about 40 nm to 80 nm.

When the first passivation layer 191 and the second passivation layer 192 are formed, hydrogen (H) is injected into a process chamber and the first and second passivation layers 191 and 192 contain hydrogen (H) due to the injected hydrogen (H). Thus, a defect, for example, dangling bonds existing at and around the back surface of the substrate 110 are converted into stable bonds by hydrogen (H) contained in the first and second passivation layers 191 and 192. As a result, the first and second passivation layers 191 and 192 perform a passivation function capable of preventing or reducing a recombination and/or a disappearance of carriers moving to the surface of the substrate 110, and thus, reduce an amount of carriers lost by the defect at and around the surface of the substrate 110.

Further, the first and second passivation layers 191 and 192 reflect light passing through the substrate 110 back to the substrate 110, and thus, increase the efficient use of an amount of light incident on the substrate 110.

In addition, the second passivation layer 192 prevents hydrogen (H), which is contained in the first passivation layer 191 and performs the passivation function, from moving to the opposite side of the surface of the substrate 110, and prevents the back electrode part 150 from reducing the passivation effect, thereby further improving the passivation effect of the surface of the substrate 110.

In general, silicon nitride (SiNx) has the characteristic of positive fixed charges, and (silicon oxide (SiOx) and aluminum oxide (AlxOy) have the characteristic of negative fixed charges.

Hence, when the substrate 110 is of the p-type, a layer formed of silicon nitride (SiNx) may be formed directly on the back surface of the substrate 110 to perform the passivation function. As a result, because positive charges (i.e., holes) moving to the silicon nitride (SiNx) layer have the same polarity as the silicon nitride (SiNx) layer, the holes are pushed out of the silicon nitride (SiNx) layer because of the polarity of the silicon nitride (SiNx) layer.

Accordingly, when the substrate 110 is of the p-type, the first passivation layer 191 formed of silicon oxide (SiOx) performs not only the passivation function but also performs as a block layer which prevents an influence of a positive polarity of the second passivation layer 192 formed of silicon nitride (SiNx) on the first passivation layer 191 from reaching the back surface of the substrate 110. Because the influence of the positive polarity does not reach the back surface of the substrate 110 by the first passivation layer 191 formed of silicon oxide (SiOx), holes produced in the substrate 110 are not affected by the positive fixed charges of the second passivation layer 192 and stably and smoothly move to the back surface of the substrate 110.

When the thickness of the first passivation layer 191 formed of silicon oxide (SiOx) is equal to or greater than about 200 nm, the first passivation layer 191 stably blocks the influence of the fixed charges of the second passivation layer 192 to thereby stably perform the movement of holes to the back surface of the substrate 110. When the thickness of the first passivation layer 191 formed of silicon oxide (SiOx) is equal to or less than about 300 nm, the movement of holes to the back surface of the substrate 110 is stably performed without unnecessarily increasing time and cost for manufacturing the first passivation layer 191.

In other words, when the first passivation layer 191 is formed of silicon oxide (SiOx) and the second passivation layer 192 is formed of silicon nitride (SiNx) under the condition of the p-type substrate 110, most of the passivation function is performed not by the first passivation layer 191 but by the second passivation layer 192. Further, the first passivation layer 191 prevents the detrimental influence of the fixed charges of the second passivation layer 192 on the movement of holes.

Alternatively, a layer formed of aluminum oxide (AlxOy) having the characteristic of negative fixed charges may be formed directly on the p-type substrate 110. Because positive charges (i.e., holes) moving to the aluminum oxide (AlxOy) layer have a polarity opposite the aluminum oxide (AlxOy) layer, the holes are drawn to the passivation layer 190 due to the polarity of the aluminum oxide (AlxOy) layer. Further, negative charges (i.e., electrons) having the same polarity as the aluminum oxide (AlxOy) layer are pushed out of the aluminum oxide (AlxOy) layer due to the polarity of the aluminum oxide (AlxOy) layer. As a result, when the first passivation layer 191 formed of aluminum oxide (AlxOy) is formed on the p-type substrate 110, an amount of holes moving to the back surface of the substrate 110 further increases because of an influence of negative fixed charges.

Accordingly, when the first passivation layer 191 is formed of aluminum oxide (AlxOy) and the second passivation layer 192 is formed of silicon nitride (SiNx) under the condition of the p-type substrate 110, most of the passivation function is performed by the first passivation layer 191, and the second passivation layer 192 mainly protects the passivation function from the back electrode part 150.

Because the fixed charges of the second passivation layer 192 do not adversely affect the movement of holes when the first passivation layer 191 is formed of aluminum oxide (AlxOy), the thickness of the first passivation layer 191 formed of aluminum oxide (AlxOy) is much less than the thickness of the first passivation layer 191 formed of silicon oxide (SiOx). As described above, the first passivation layer 191 formed of aluminum oxide (AlxOy) may have a thickness of about 30 nm to 70 nm.

When the thickness of the first passivation layer 191 formed of aluminum oxide (AlxOy) is equal to or greater than about 30 nm, the first passivation layer 191 stably and efficiently performs the passivation function. When the thickness of the first passivation layer 191 formed of aluminum oxide (AlxOy) is equal to or less than about 70 nm, the movement of holes to the back surface of the substrate 110 is stably performed without unnecessarily increasing time and cost for manufacturing the first passivation layer 191.

As above, an amount of carriers lost by the defect at and around the surface of the substrate 110 is reduced by the passivation layer 190, which is positioned on the back surface of the substrate 110 and includes the first passivation layer 191 and the second passivation layer 192. As a result, the efficiency of the solar cell 11 is improved.

Each of the plurality of BSF regions 172 positioned at the back surface of the substrate 110 is a region (for example, a p⁺-type region) that is more heavily doped than the substrate 110 with impurities of the same conductive type as the substrate 110.

A potential barrier is formed by a difference between impurity concentrations of a first conductive region (for example, a p-type region) of the substrate 110 and the BSF regions 172. Hence, the potential barrier prevents or reduces electrons from moving to the BSF regions 172 used as a moving path of holes and makes it easier for holes to move to the BSF regions 172. Thus, the BSF regions 172 reduce an amount of carriers lost by a recombination and/or a disappearance of the electrons and the holes at and around the back surface of the substrate 110 and accelerate a movement of desired carriers (for example, holes), thereby increasing an amount of carriers moving to the back electrode part 150.

The back electrode part 150 is positioned on the passivation layer 190 and includes a back electrode (or a second electrode) 155 and a plurality of back bus bars (or a plurality second bus bars) 152 connected to the back electrode 155.

The back electrode 155 is positioned on the passivation layer 190 except a formation area of the back bus bars 152. Alternatively, the back electrode 155 may be not positioned at an edge of the back surface of the substrate 110.

The back electrode 155 includes a plurality of contact portions 151, which pass through the passivation layer 190 and are connected to the plurality of BSF regions 172. Hence, the back electrode 155 is selectively (or locally) connected to a portion (i.e., the plurality of BSF regions 172) of the substrate 110 through the plurality of contact portions 151.

As shown in FIG. 1, the plurality of contact portions 151 are connected to the substrate 110 at a predetermined distance (for example, about 0.5 mm to 1 mm) therebetween. Each contact portion 151 has various shapes such as a circle, an oval, and a polygon. Alternatively, each contact portion 151 may have a stripe shape in the same manner as the front electrode 141, and thus, may be electrically connected to the substrate 110 and may elongate in one direction. In this instance, the number of contact portions 151 having the stripe shape is much less than the number of contact portions 151 having the circle, the oval, or the polygon.

The contact portions 151 collect carriers (for example, holes) moving to the substrate 110 and transfer the carriers to the back electrode 155.

Because the plurality of BSF regions 172, which have the conductivity higher than the substrate 110 due to the impurity concentration higher than the substrate 110, adjoin the plurality of contact portions 151, the mobility of carriers from the substrate 110 to the contact portions 151 is improved.

The back electrode 155 is formed of a conductive material such as aluminum (Al). Other materials may be used.

The contact portions 151 contacting the substrate 110 may contain only the material of the back electrode 155 or may contain a mixture of the materials of the passivation layer 190 and the substrate 110 as well as the material of the back electrode 155.

As described above, the second passivation layer 192 prevents a combination between the metal material such as aluminum (Al) contained in the back electrode 155 and silicon of the substrate 110, thereby preventing a reduction in the passivation effect resulting from the material contained in the back electrode 155.

The plurality of back bus bars 152 connected to the back electrode 155 are positioned on the passivation layer 190 on which the back electrode 155 is not positioned. The back bus bars 152 extend in the same direction as the front bus bars 142 and have a stripe shape. The back bus bars 152 and the front bus bars 142 are positioned on the opposite sides of the substrate 110. The back bus bars 152 and the front bus bars 142 may be aligned.

The back bus bars 152 collect carriers transferred from the back electrode 155 similar to the front bus bars 142. Thus, the back bus bars 152 may be formed of a material having the conductivity higher than the back electrode 155. For example, the back bus bars 152 contain at least one conductive material such as silver (Ag).

The back bus bars 152 are connected to the external device, and carriers (for example, holes) collected by the back bus bars 152 are output to the external device.

Unlike the configuration illustrated in FIG. 1, the back bus bars 152 may partially overlap the back electrode 155. In this instance, because a contact resistance of the back bus bars 152 may decrease by an increase in an area of the back bus bars 152 contacting the back electrode 155, an amount of carriers transferred from the back electrode 155 to the back bus bars 152 may increase. Further, the back electrode 155 may be positioned on the passivation layer 190 on which the back bus bars 152 are formed. In this instance, the back bus bars 152 may be positioned on the back electrode 155 with the back bus bars 152 and the front bus bars 142 being positioned on the opposite sides of the substrate 110. Thus, because the back electrode 155 may be positioned on the passivation layer 190 irrespective of the formation location of the back bus bars 152, the back electrode 155 may be more easily formed.

In an alternative example, each of the back bus bars 152 may be formed of a plurality of conductors, which have a circle, an oval, or a polygon shape instead of the stripe shape and be disposed at a uniform or non-uniform distance therebetween along an extension direction of the front bus bars 142. In this instance, because the use of an expensive material, for example, silver (Ag) for the back bus bars 152 decreases, the manufacturing cost of the solar cell 11 is reduced.

The number of back bus bars 152 shown in FIG. 1 may vary, if necessary or desired.

An operation of the solar cell 11 having the above-described structure is described below.

When light irradiated to the solar cell 11 is incident on the substrate 110, which is the semiconductor part, through the anti-reflection layer 130 and the emitter region 121, a plurality of electron-hole pairs are generated in the substrate 110 by light energy produced based on the incident light. In this instance, because a reflection loss of the light incident on the substrate 110 is reduced by the anti-reflection layer 130, an amount of light incident on the substrate 110 increases.

The electron-hole pairs are separated into electrons and holes by the p-n junction of the substrate 110 and the emitter region 121. Then, the separated electrons move to the n-type emitter region 121, and the separated holes move to the p-type substrate 110. The electrons moving to the emitter region 121 are collected by the front electrodes 141 and the front bus bars 142 and then are transferred to the front bus bars 142. The holes moving to the substrate 110 are transferred to the contact portions 151 and then are collected by the back bus bars 152. When the front bus bars 142 are connected to the back bus bars 152 using electric wires, current flows therein to thereby enable use of the current for electric power.

Further, when the emitter region 121 is formed using the ion implantation method, the sheet resistance of the emitter region 121 increases. Therefore, an amount of carriers lost by impurities in the emitter region 121 greatly decreases.

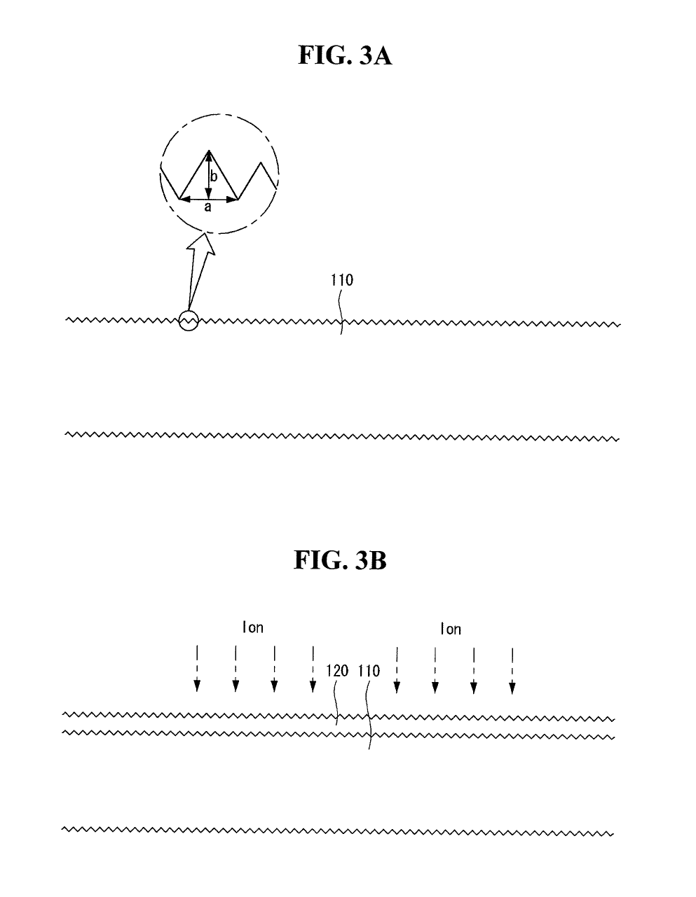

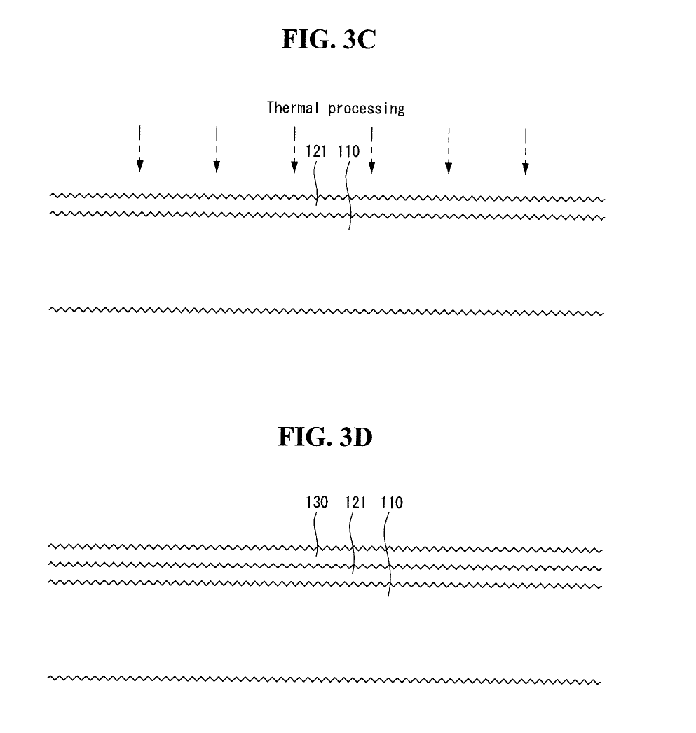

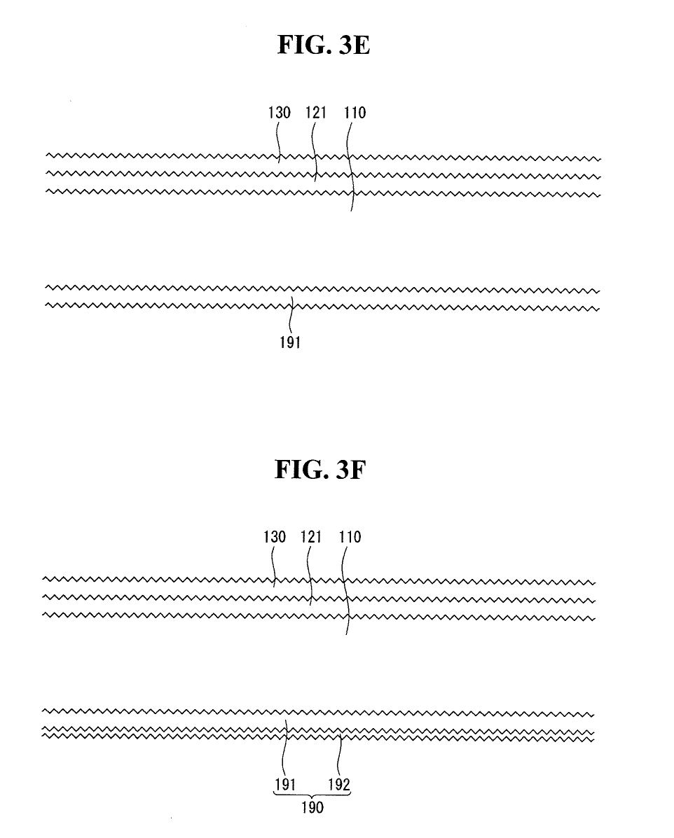

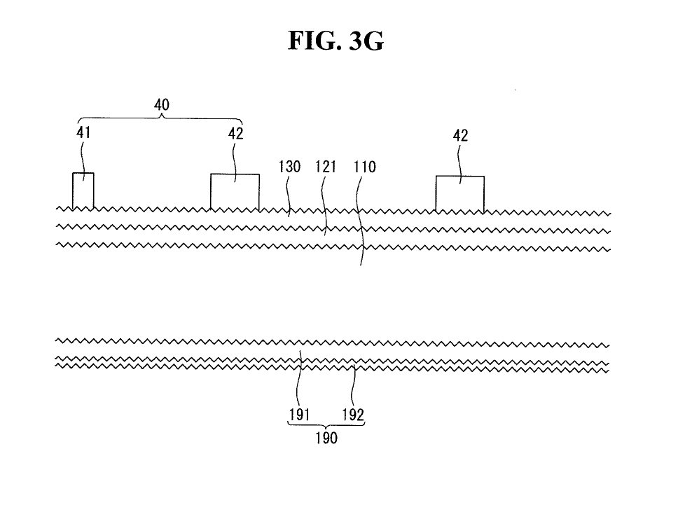

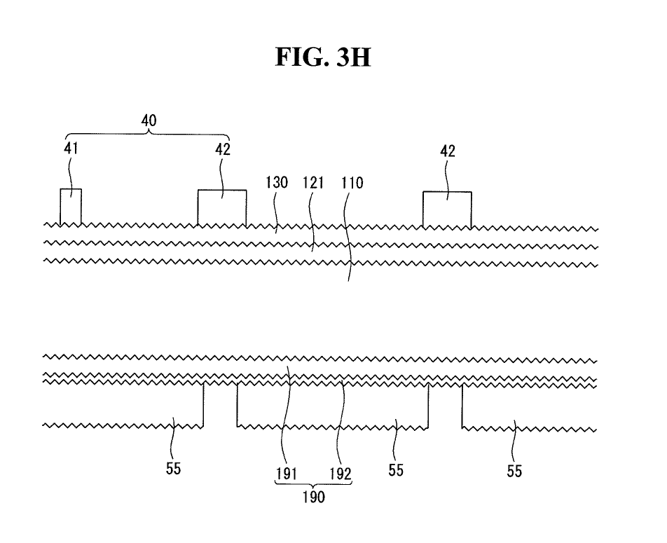

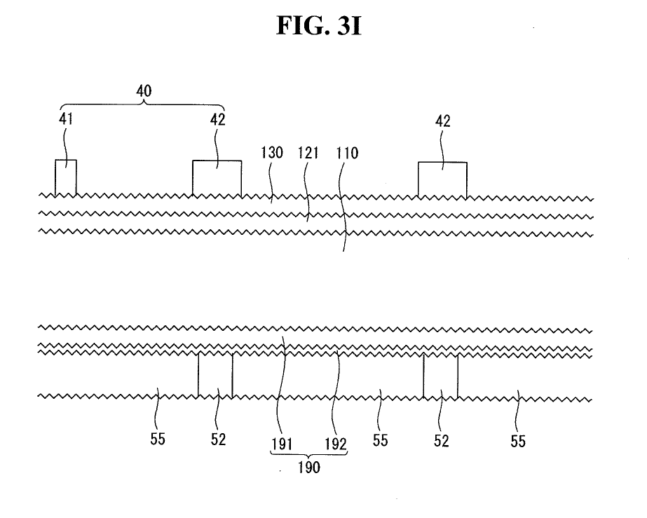

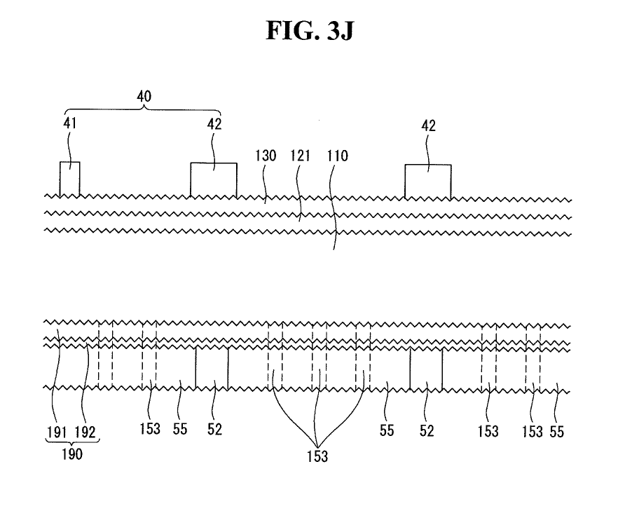

An exemplary method for manufacturing a solar cell according to an embodiment of the invention is described with reference to FIGS. 3A to 3J.

First, as shown in FIG. 3A, a texturing process is performed on a crystalline semiconductor substrate 110 formed of single crystal silicon, polycrystalline silicon, etc., to form a textured surface corresponding to an uneven surface having a plurality of projections and a plurality of depressions or having uneven characteristics on a front surface and a back surface of the substrate 110. When the substrate 110 is formed of single crystal silicon, the texturing process may be performed using a base solution such as KOH and NaOH. When the substrate 110 is formed of polycrystalline silicon, the texturing process may be performed using an acid solution such as HF and HNO₃.

In the textured surface, a maximum diameter “a” and a maximum height “b” of each of the plurality of projections may be approximately 5 μm to 15 μm, and an aspect ratio “b/a” of each projection may be approximately 0.2 to 2.

In FIGS. 3A to 3J, all of the projections of the front and back surfaces of the substrate 110 are shown to equally have a maximum diameter “a” and a maximum height “b” for the sake of convenience. However, the projections actually having the different maximum diameters “a” and the different maximum heights “b” are formed on each of the front and back surfaces of the substrate 110.

As above, because the front surface and the back surface of the substrate 110 respectively have the textured surfaces having the same characteristics through use of one process, the front surface and the back surface of the substrate 110 are substantially the same as each other in a roughness per unit area of the textured surface. However, a roughness of the textured front surface of the substrate 110 may be different from a roughness of the textured back surface of the substrate 110.

In the embodiment of the invention, the substrate 110 is of a p-type. Alternatively, the substrate 110 may be of an n-type in another embodiment of the invention.

Next, as shown in FIG. 3B, ions of a group V element or ions of a group III element are implanted into one surface, for example, the front surface of the substrate 110 using an ion implantation method to form an impurity region 120 at the front surface (i.e., the incident surface) of the substrate 110.

Because the impurity region 120 is a state in which n-type (or p-type) impurities are physically implanted into the substrate 110, a sheet resistance of the impurity region 120 is several hundreds of Ω/sq. Further, because the impurity region 120 is in an inactive state, the impurity region 120 cannot serve as an emitter region of the solar cell 11.

After the impurity region 120 is formed using the ion implantation method, an activation process, which performs a thermal process on the substrate 110 having the impurity region 120 in the atmosphere of oxygen (O₂) to activate the impurity region 120 positioned at the front surface of the substrate 110, is performed to rearrange damaged silicon lattices and combine impurities of the impurity region 120 and silicon, or a combine the impurities. Hence, the impurity region 120 is formed to serve as an emitter region 121, and by the activation process, a damaged area generated in the ion implantation is recovered. In this instance, the thermal process for activating the impurity region 120 may be performed at a temperature of about 700° C. to 900° C.

Afterwards, a silicon oxide film (i.e., a thermal oxide film), which is produced at the surface of the substrate 110 by a combination of silicon of the substrate 110 and oxygen injected for the activation process, is removed using a dilute HF (DHF) solution. Thus, by the activation process, the impurity region 120 formed inside the substrate 110 is changed to the emitter region 121. In addition, not only a damage such as a damage of the silicon lattices of the surface of the substrate 110 by ions impinging on the surface of the substrate 110 due to the ion implantation, but also a defect, for example, dangling bonds existing at and around the surface of the substrate 110, are addressed or solved. In this instance, the emitter region 121 may have a sheet resistance of about 60 Ω/sq. to 120 Ω/sq.

In other words, a rearrangement phenomenon of the silicon lattices damaged when ions impinge on the surface of the substrate 110 is performed by the recrystallization of silicon when heat is applied at a temperature (for example, about 700° C. to 900° C.) around a recrystallization temperature of the substrate 110. Thus, the damaged silicon lattices are rearranged as the stable silicon lattices through the thermal process (i.e., the activation process) in the atmosphere of oxygen (O₂) and are recovered or annealed.

As above, when the emitter region 121 is formed using the ion implantation method, the emitter region 121 is formed only at the desired surface (for example, the front surface) of the substrate 110. Therefore, a separate process for removing the emitter region 121 formed at the undesired surface (for example, the back surface) of the substrate 110 is not necessary. Thus, the cost and time for manufacturing the solar cell 11 are reduced.

Unlike the embodiment of the invention, when the emitter region 121 is formed using a thermal diffusion method, the emitter region 121 is formed at both the front and back surfaces of the substrate 110. Thus, a process for removing the emitter region 121 formed at the back surface of the substrate 110 is necessary. More specifically, it is necessary to perform a process, which forms an etch stop layer on an undesired etching region (for example, the front surface) of the emitter region 121 and then removes the etch stop layer after the completion of the etching process. Further, the emitter region formed at the back surface of the emitter region 121 is non-uniformly etched. Even if the etch stop layer is used, an etchant penetrates the etch stop layer, and thus, may generate a damage of the emitter region 121 formed at the front surface of the substrate 110 or changes in the characteristic of the emitter region 121. When only the desired portion of the emitter region 121 is etched by exposing only the back surface of the substrate 110 to the etchant without forming a separate etch stop layer, the front surface as well as the back surface of the substrate 110 may be exposed to the etchant due to an error, etc., of the process. Hence, the undesired portion of the emitter region 121 may be etched.

Alternatively, before the emitter region 121 is formed using the thermal diffusion method, a separate diffusion protection layer is formed on the surface (for example, the back surface) of the substrate 110 when the emitter region will not be formed. Hence, the emitter region 121 may be formed only at the front surface of the substrate 110. However, in this instance, after the diffusion protection layer is formed, a process for removing the diffusion protection layer is necessary. Therefore, the cost and time for manufacturing the solar cell increase.

However, in the embodiment of the invention, the ion implantation is performed only on the desired surface (for example, the front surface) of the substrate 110 using the ion implantation method, in which an implantation concentration and an implantation depth of ions are controlled more easily than the thermal diffusion method, to form the emitter region 121 at the front surface of the substrate 110. Thus, the emitter region 121 is formed using the ion implantation method that is simpler and cheaper than the thermal diffusion method.

Further, in the embodiment of the invention, because the process for removing the emitter region formed at the back surface of the substrate 110 is not necessary, the back surface of the substrate 110 has the textured surface in the same manner as the front surface of the substrate 110.

However, if necessary, a polishing process for converting the textured back surface of the substrate 110 into a planarization surface may be performed. The polishing process may be performed before the emitter region 121 is formed or before a passivation layer 190 is formed subsequent to the formation of the emitter region 121. As above, when the back surface of the substrate 110 is without the textured surface but with the planarization surface through the polishing process, a loss of light passing through the substrate 110 may further decrease. Further, the light passing through the substrate 110 may be more easily reflected back to the substrate 110.

Next, as shown in FIG. 3D, an anti-reflection layer 130 is formed on the emitter region 121 formed at the front surface of the substrate 110 using a chemical vapor deposition (CVD) method such as a plasma enhanced CVD (PECVD) method. The anti-reflection layer 130 may be formed of silicon nitride (SiNx:H) having a thickness of about 70 nm to 80 nm and a refractive index of about 2.0 to 2.1.

Next, as shown in FIGS. 3E to 3F, a first passivation layer 191 and a second passivation layer 192 are sequentially stacked on the back surface of the substrate 110 using the PECVD method, etc., to complete the passivation layer 190. In this instance, the first passivation layer 191 may be formed of silicon oxide (SiOx) or aluminum oxide (AlxOy), and the second passivation layer 192 may be formed of silicon nitride (SiNx).

When the first passivation layer 191 is formed of silicon oxide (SiOx), the first passivation layer 191 may have a thickness of about 200 nm to 300 nm. When the first passivation layer 191 is formed of aluminum oxide (AlxOy), the first passivation layer 191 may have a thickness of about 30 nm to 70 nm.

Further, the second passivation layer 192 may have a thickness of about 40 nm to 80 nm.

Next, as shown in FIG. 3G, a paste containing silver (Ag) is applied on a desired portion of the anti-reflection layer 130 using a screen printing method and then is dried at about 120° C. to 200° C. to form a front electrode part pattern 40. The front electrode part pattern 40 includes a front electrode pattern 41 and a front bus bar pattern 42, which extend in a crossing direction between them.

Next, as shown in FIG. 3H, a paste containing aluminum (Al) is applied on a desired portion of the passivation layer 190 using the screen printing method and then is dried at about 120° C. to 200° C. to form a back electrode pattern 55.

Next, as shown in FIG. 3I, a paste containing silver (Ag) is applied on a desired portion of the passivation layer 190 using the screen printing method and then is dried to form a plurality of back bus bar patterns 52. Unlike the process illustrated in FIG. 3I, the plurality of back bus bar patterns 52 may be positioned on the back electrode pattern 55 and a portion of the back electrode pattern 55, and thus, may partially overlap the back electrode pattern 55.

In the embodiment of the invention, each of the back bus bar patterns 52 has a stripe shape, which elongates (or extends) in one direction. Alternatively, the plurality of back bus bar patterns 52 having various shapes such as a circle, an oval, and a polygon may be disposed at a uniform or non-uniform distance therebetween in one direction.

In the embodiment of the invention, a formation order of the front electrode part pattern 40, the back electrode pattern 55, and the back bus bar patterns 52 may vary.

Next, as shown in FIG. 3J, when laser beams are selectively irradiated onto a determined portion of the back electrode pattern 55, molten mixtures 153, in which the back electrode pattern 55, the passivation layer 190 underlying the back electrode pattern 55, and the substrate 110 are mixed with one another, are formed. In an alternative example, when each contact portion 151 has a stripe shape, an irradiated area of the laser beams may have a stripe shape elongating (or extending) in a fixed direction.

A wavelength and an intensity of the laser beams are determined depending on the materials and the thicknesses of the back electrode pattern 55 and the passivation layer 190 underlying the back electrode pattern 55, etc.

Afterwards, the substrate 110, on which the back electrode pattern 55, the back bus bar patterns 52, and the front electrode part pattern 40 are formed, is fired at a temperature of about 750° C. to 800° C. to form a back electrode part 150 including a back electrode 155 having a plurality of contact portions 151 and a plurality of back bus bars 152, and a front electrode part 140 including a plurality of front electrodes 141 and a plurality of front bus bars 142, as well as a plurality of BSF regions 172. Hence, the solar cell 11 shown in FIGS. 1 and 2 is completed.

More specifically, when the thermal process is performed, the front electrode part pattern 40 passes through a portion of the anti-reflection layer 130 contacting the front electrode part pattern 40 due to lead (Pb) contained in the front electrode part pattern 40, and thus, contacts the emitter region 121. Hence, the front electrode part 140 including the plurality of front electrodes 141 and the plurality of front bus bars 142 is formed. In this instance, the front electrode pattern 41 and the front bus bar pattern 42 of the front electrode part pattern 40 are or form the plurality of front electrodes 141 and the plurality of front bus bars 142, respectively.

Further, the molten mixtures 153 of the back electrode pattern 55, the passivation layer 190, and the substrate 110 contact the substrate 110 and are or form the plurality of contact portions 151. Hence, the back electrode 155 having the plurality of contact portions 151 is completed. Further, the plurality of back bus bar patterns 52 are connected to the back electrode 155 to form the plurality of back bus bars 152. As above, when the plurality of contact portions 151 are formed using the laser beams, each contact portion 151 may contain the materials of the passivation layer 190 and the substrate 110 as well as the material of the back electrode 155.

Because the components 121, 110, and 190 are chemically combined with the metal material contained in each of the patterns 40, 55, and 52 in the thermal process, a contact resistance between the front electrode part 140 and the emitter region 121, a contact resistance between the contact portions 151 and the substrate 110, and a contact resistance between the back electrode 155 and the back bus bars 152 are reduced. Hence, a flow of carriers between them is improved.

Aluminum (Al) contained in the back electrode 155 is diffused into the substrate 110 contacting the contact portions 151 in the thermal process to form the plurality of BSF regions 172, which are more heavily doped than the substrate 110 with impurities of the same conductive type as the substrate 110, at locations where the substrate 110 adjoin the contact portions 151.

Instead of the laser beams, the plurality of contact portions 151 may be formed by sequentially removing a portion of the second passivation layer 192, and a portion of the first passivation layer 191 underlying the second passivation layer 192 and exposing a portion of the back surface of the substrate 110.

In other words, as shown in FIGS. 3A to 3G, after the emitter region 121, the anti-reflection layer 130, and the passivation layer 190 are formed on the substrate 110, a plurality of exposure portions for exposing a portion of the substrate 110 are formed by removing a portion of the passivation layer 190. In this instance, the exposure portions of the passivation layer 190 may be formed using a dry etching method, a wet etching method, or a laser beam irradiation method. Each of the exposure portions may have a stripe shape depending on the shape of the contact portions 151 or may have a circle, an oval, and a polygon disposed in a fixed direction.

Next, the front electrode part pattern 40 is formed on the anti-reflection layer 130 using the screen printing method, and the back electrode pattern 55 is formed on the passivation layer 190 and the exposed portion of the substrate 110 using the screen printing method. Further, the plurality of back bus bar patterns 52 adjoining the back electrode pattern 55 are formed on the passivation layer 190 using the screen printing method.

Next, as described above, the thermal process is performed on the substrate 110 having the patterns 40, 55, and 52 to form the front electrode part 140 connected to the emitter region 121, the back electrode 155 having the plurality of contact portions 151 connected to the substrate 110 through the plurality of exposure portions of the passivation layer 190, and the plurality of back bus bars 152 connected to the back electrode 155, as well as the plurality of BSF regions 172 at the substrate 110 adjoining the plurality of contact portions 151. In this instance, because the plurality of contact portions 151 are formed in the portion of the substrate 110 exposed by removing the passivation layer 190, each contact portion 151 may contain only the material of the back electrode 155.

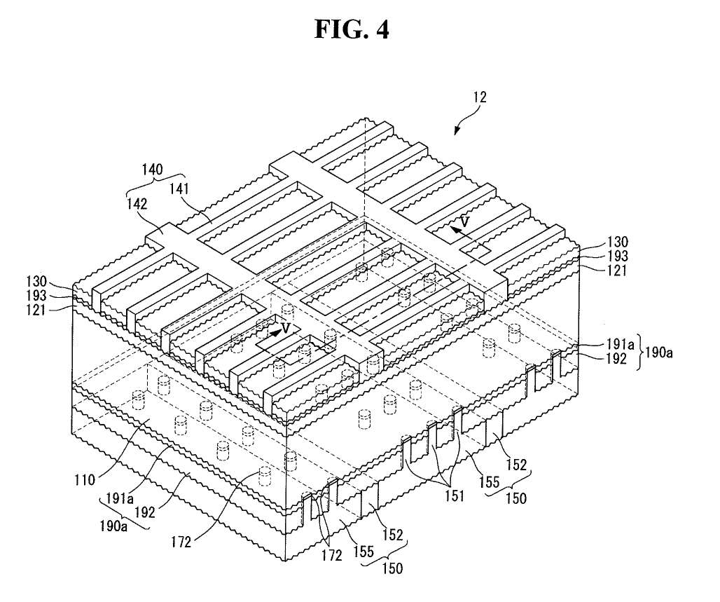

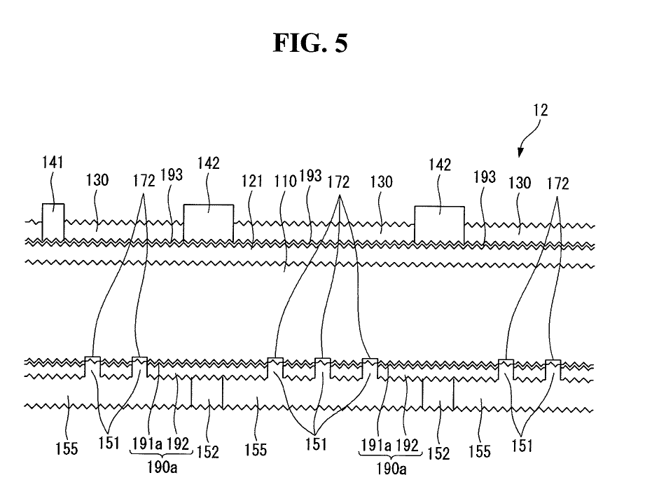

A solar cell 12 according to another example embodiment of the invention is described below with reference to FIGS. 4 and 5.

The solar cell 12 shown in FIGS. 4 and 5 has the structure similar to the solar cell 11 shown in FIGS. 1 and 2.

More specifically, the solar cell 12 includes a substrate 110, an emitter region 121 which is positioned only at a front surface of the substrate 110 having a textured surface corresponding to an uneven surface through a texturing process and is formed using an ion implantation method, an anti-reflection layer 130 positioned on the emitter region 121, a passivation layer 190a which is positioned on a back surface of the substrate 110 having a textured surface corresponding to an uneven surface and includes first and second passivation layers 191a and 192, a front electrode part 140 which is connected to the emitter region 121 and includes a plurality of front electrodes 141 and a plurality of front bus bars 142, a back electrode part 150 which is positioned on the passivation layer 190a, is connected to the substrate 110, and includes a back electrode 155 having a plurality of contact portions 151 and a plurality of back bus bars 152, and a plurality of BSF regions 172 which are selectively positioned at the back surface of the substrate 110 and are connected to the plurality of contact portions 151 of the back electrode part 150.

However, unlike the solar cell 11 shown in FIGS. 1 and 2, the solar cell 12 shown in FIGS. 4 and 5 further includes a front passivation layer 193 between the emitter region 121 and the anti-reflection layer 130. The front passivation layer 193 may be formed of the same material as the first passivation layer 191a of the passivation layer 190a positioned on the back surface of the substrate 110.

In the embodiment of the invention, the front passivation layer 193 and the first passivation layer 191a of the passivation layer 190a are formed of a silicon oxide (SiOx) film (i.e., a thermal oxide film). Each of the front passivation layer 193 and the first passivation layer 191a of the passivation layer 190a has a thickness of about 15 nm to 30 nm.

Accordingly, the front passivation layer 193 positioned on the front surface of the substrate 110 as well as the anti-reflection layer 130 perform a passivation function of the substrate 110, thereby greatly reducing an amount of carriers lost by a defect existing at and around the surface of the substrate 110.

The characteristic of the thermal oxide film formed using a thermal oxide method is much more excellent than the characteristic of the silicon oxide (SiOx) layer formed using a layer forming method such as the PECVD method. Thus, because the layers formed on the front and back surfaces of the substrate 110 using the thermal oxide method perform the passivation function, the passivation effect is further improved.

The front passivation layer 193 and the first passivation layer 191a of the passivation layer 190a, each of which is the thermal oxide film, are formed in a process, in which ions are implanted into the substrate 110 using the ion implantation method to form the impurity region and then the activation process is performed on the impurity region in the atmosphere of oxygen (O₂) to thereby recover a damage of the silicon lattices of the surface of the substrate 110 by ions impinging on the surface of the substrate 110, as described above with reference to FIGS. 1 to 3J.

Accordingly, the front passivation layer 193 and the first passivation layer 191a of the passivation layer 190a are formed in the thermal process in the atmosphere of oxygen (O₂) performed after the ion implantation method without a separate process. Therefore, a separate film forming process for forming the front passivation layer 193 and the first passivation layer 191a is not necessary. As a result, manufacturing time of the solar cell 12 is reduced.

As above, in the solar cell 12 according to the embodiment of the invention, when the impurity region is activated after the ion implantation to form the emitter region 121, the surface of the substrate 110 damaged by the ion implantation method is recovered. Further, an amount of carriers lost by the defect resulting from the damage of the silicon lattices of the substrate 110 is greatly reduced, and the front passivation layer 193 and the first passivation layer 191a which are generated in the recovery process and have the excellent passivation effect, perform the passivation function. Therefore, an amount of carriers lost by the defect at and around the surface of the substrate 110 is further reduced. As a result, the efficiency of the solar cell 12 shown in FIGS. 4 and 5 are greater than the efficiency of the solar cell 11 shown in FIGS. 1 and 2.

As above, when the passivation layer 190a includes the first passivation layer 191a (i.e., the thermal oxide film) and the second passivation layer 192 (i.e., the silicon nitride layer), most of the passivation function is performed by the first passivation layer 191a. The front electrode part 140 collects carriers moving through the front passivation layer 193.

In the solar cell 12 according to the embodiment of the invention, when the thickness of each of the front passivation layer 193 and the first passivation layer 191a is equal to or greater than about 15 nm, the damage of the silicon lattices of the substrate 110 damaged by the ion implantation method is more effectively recovered, and the passivation effect is more efficiently obtained. Further, when the thickness of each of the front passivation layer 193 and the first passivation layer 191a is equal to or less than about 30 nm, an increase in thermal processing time for the unnecessary activation process is prevented, the damage of the silicon lattice of the substrate 110 is more effectively recovered, and the passivation effect is more efficiently obtained. Further, because the movement of carriers to the front electrode part 140 through the front passivation layer 193 is more smoothly performed, the collection of carriers by the front electrode part 140 is more stably performed.

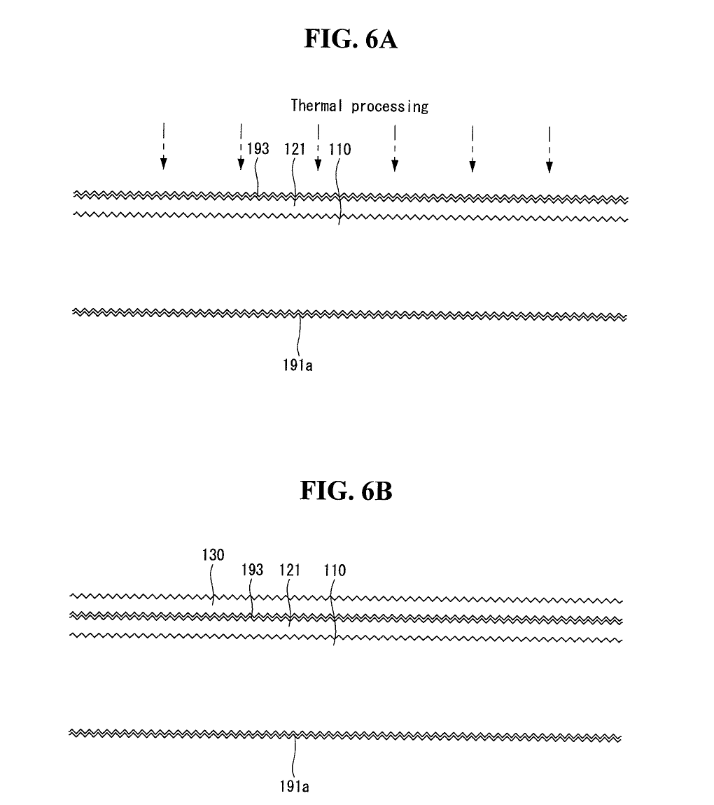

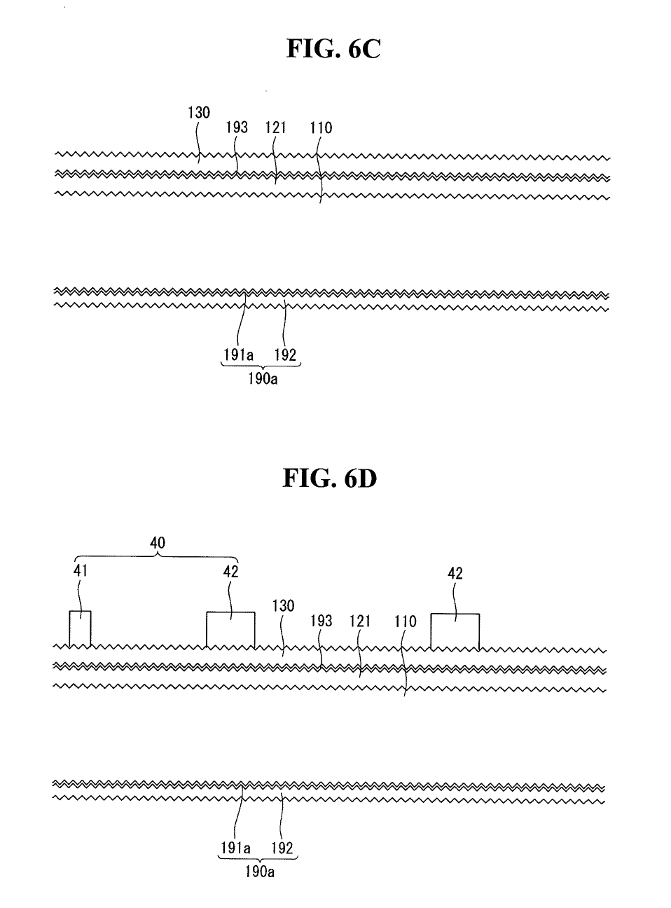

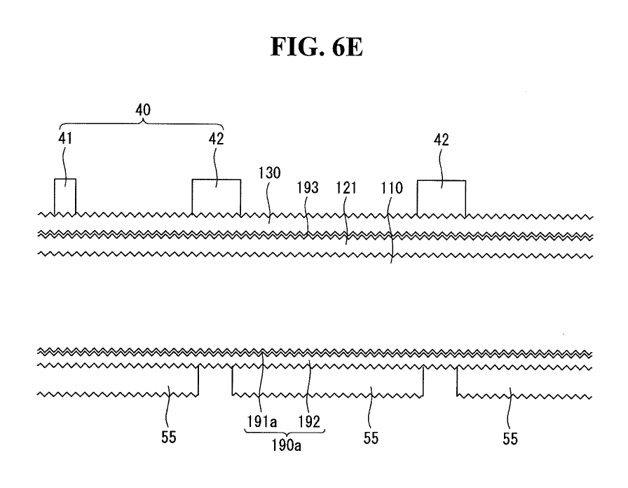

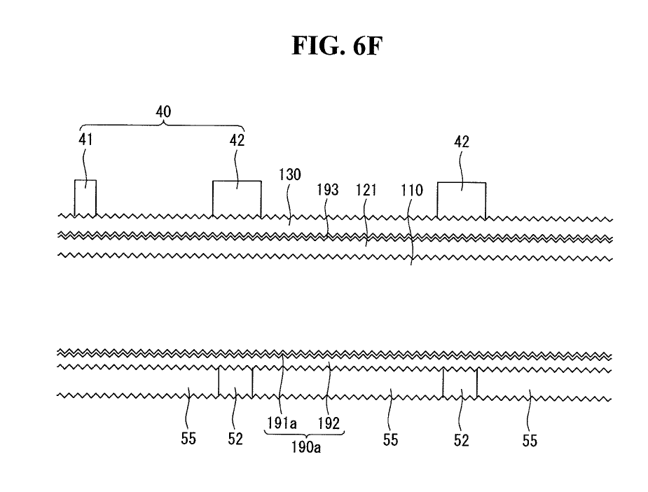

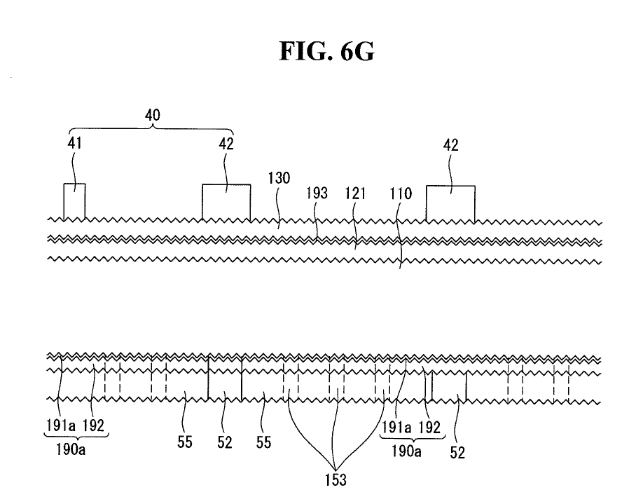

A method for manufacturing the solar cell 12 is described below with reference to FIGS. 6A to 6G as well as FIGS. 3A to 3J. In a manner as described above with reference to FIGS. 3A and 3B, a texturing process is performed on a substrate 110 to form a textured surface corresponding to an uneven surface on a front surface and a back surface of the substrate 110. An impurity region 120 is formed at one surface, for example, the front surface of the substrate 110 using an ion implantation method.

Next, as shown in FIG. 6A, in a manner as described above with reference to FIG. 3C, a thermal process is performed on the substrate 110 at a temperature of about 700° C. to 900° C. in the atmosphere of oxygen (O₂) to activate the impurity region 120. Hence, an emitter region 121 is formed.

Meanwhile, a thermal oxide film is formed on the front surface and the back surface of the substrate 110 through the activation process performed in the atmosphere of oxygen to thereby form a front passivation layer 193 on the front surface of the substrate 110 and a first passivation layer 191a of a passivation layer 190a on the back surface of the substrate 110. A thickness of each of the thermal oxide films 193 and 191a may be about 15 nm to 30 m.

In the method for manufacturing the solar cell 12, unlike the process illustrated in FIG. 3C, a process for removing the thermal oxide films produced in the activation process of the atmosphere of oxygen is not necessary.

Next, in a manner as described above with reference to FIG. 3D, an anti-reflection layer 130 is formed on the front passivation layer 193 using the PECVD method, etc. In a manner as described above with reference to FIG. 3F, a second passivation layer 192 is formed on the first passivation layer 191a. Hence, the passivation layer 190a including the first passivation layer 191a and the second passivation layer 192 is completed as shown in FIG. 6C. In this instance, a formation order of the anti-reflection layer 130 and the second passivation layer 192 may vary.

Next, in a manner as described above with reference to FIGS. 3G to 3I, a front electrode part pattern 40 is formed on the anti-reflection layer 130, and a back electrode pattern 55 and a plurality of back bus bar patterns 52 are formed on the passivation layer 190a as shown in FIGS. 6D to 6F.

Next, as described above with reference to FIG. 3J, laser beams are irradiated onto the back surface of the substrate 110 to form a molten mixture 153, in which the back electrode pattern 55, the passivation layer 190a underlying the back electrode pattern 55, and the substrate 110 are mixed with one another, as shown in FIG. 6G. Afterwards, the thermal process is performed on the substrate 110 having the patterns 55, 52, and 40 at a temperature of about 750° C. to 800° C. to form a back electrode part 150 including a back electrode 155 having a plurality of contact portions 151 and a plurality of back bus bars 152, and a front electrode part 140 including a plurality of front electrodes 141 and a plurality of front bus bars 142, as well as a plurality of BSF regions 172. Hence, the solar cell 12 shown in FIGS. 4 and 5 is completed.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a solar cell, the method comprising:
forming an emitter region of a second conductive type opposite a first conductive type at a first surface of a substrate of the first conductive type by using an ion implantation method;
forming a passivation layer on a second surface positioned opposite the first surface of the substrate; and
forming a first electrode, which is positioned on the first surface of the substrate and is connected to the emitter region, and a second electrode, which is positioned on the second surface of the substrate and is selectively connected to the substrate through the passivation layer.

2. The method of claim 1, wherein the forming of the emitter region includes:
implanting impurities of the second conductive type into the first surface of the substrate using the ion implantation method to form an impurity region at the first surface of the substrate; and
performing a thermal process on the substrate having the impurity region in an atmosphere of oxygen to convert the impurity region into the emitter region and to form first and second thermal oxide films on the first and second surfaces of the substrate.

3. The method of claim 2, wherein the thermal process is performed at a temperature of 700° C. to 900° C.

4. The method of claim 2, further comprising removing the first and second thermal oxide films.

5. The method of claim 2, wherein the passivation layer is formed on the second thermal oxide film positioned on the second surface of the substrate.

6. The method of claim 2, further comprising forming an anti-reflection layer on the first thermal oxide film positioned on the first surface of the substrate,
wherein the first electrode is connected to the substrate through the anti-reflection layer and the first thermal oxide film.

7. The method of claim 6, wherein the anti-reflection layer is formed of silicon nitride.

8. The method of claim 2, wherein each of the first and second thermal oxide films has a thickness of substantially 15 nm to 30 nm.

9. The method of claim 4, further comprising forming an anti-reflection layer on the emitter region,
wherein the first electrode is connected to the emitter region through the anti-reflection layer.

10. The method of claim 9, wherein the anti-reflection layer is formed of silicon nitride.

11. The method of claim 1, wherein the passivation layer is formed of silicon nitride.

12. The method of claim 1, wherein the forming of the passivation layer includes:
forming a first passivation layer using silicon oxide; and
forming a second passivation layer using silicon nitride.

13. The method of claim 1, wherein the forming of the passivation layer includes:
forming a first passivation layer using aluminum oxide; and
forming a second passivation layer using silicon nitride.

14. The method of claim 1, wherein the first conductive type is a p-type, and the second conductive type is an n-type.

15. The method of claim 1, wherein the first conductive type is an n-type, and the second conductive type is a p-type.

16. The method of claim 1, further comprising, before forming the emitter region, forming a textured surface on each of the first and second surfaces of the substrate.

17. The method of claim 16, further comprising polishing the textured surface formed on the second surface of the substrate to form a flat surface.

18. A solar cell comprising:
a substrate of a first conductive type, the substrate including first and second surfaces, which are positioned opposite each other;
an emitter region of a second conductive type opposite the first conductive type, which is formed at the first surface of the substrate using an ion implantation method;
a first electrode which is positioned on the first surface of the substrate and is connected to the emitter region;
a passivation layer positioned on the second surface of the substrate; and
a second electrode which is positioned on the second surface of the substrate and is selectively connected to the substrate through the passivation layer.

19. The solar cell of claim 18, wherein the emitter region has a sheet resistance of 60 Ω/sq. to 120 Ω/sq.

20. The solar cell of claim 18, further comprising a first thermal oxide film positioned on the emitter region and a second thermal oxide film positioned on the second surface of the substrate,
wherein the passivation layer is positioned on the second thermal oxide film, and
wherein the first electrode is connected to the emitter region through the first thermal oxide film, and the second electrode is connected to the substrate through the passivation layer and the second thermal oxide film.

21. The solar cell of claim 20, wherein each of the first and second thermal oxide films has a thickness of substantially 15 nm to 30 nm.

22. The solar cell of claim 18, wherein the passivation layer is formed of silicon nitride.

23. The solar cell of claim 22, wherein the passivation layer has a thickness of substantially 40 nm to 80 nm.

24. The solar cell of claim 20, further comprising an anti-reflection layer positioned on the first thermal oxide film.

25. The solar cell of claim 24, wherein the anti-reflection layer is formed of silicon nitride.

26. The solar cell of claim 18, further comprising an anti-reflection layer positioned on the emitter region,
wherein the first electrode passes through the anti-reflection layer and contacts the emitter region.

27. The solar cell of claim 26, wherein the anti-reflection layer is formed of silicon nitride.

28. The solar cell of claim 18, wherein the passivation layer includes a first passivation layer, which is positioned on the second surface of the substrate and is formed of silicon oxide, and a second passivation layer, which is positioned on the first passivation layer and is formed of silicon nitride.

29. The solar cell of claim 28, wherein the first passivation layer has a thickness of substantially 200 nm to 300 nm, and the second passivation layer has a thickness of substantially 40 nm to 80 nm.

30. The solar cell of claim 28, wherein the first conductive type is a p-type, and the second conductive type is an n-type.

31. The solar cell of claim 28, wherein the first conductive type is an n-type, and the second conductive type is a p-type.

32. The solar cell of claim 18, wherein the passivation layer includes a first passivation layer, which is positioned on the second surface of the substrate and is formed of aluminum oxide, and a second passivation layer, which is positioned on the first passivation layer and is formed of silicon nitride.

33. The solar cell of claim 32, wherein the first passivation layer has a thickness of substantially 30 nm to 70 nm, and the second passivation layer has a thickness of substantially 40 nm to 80 nm.

34. The solar cell of claim 32, wherein the first conductive type is a p-type, and the second conductive type is an n-type.

35. The solar cell of claim 18, further comprising a field region, which adjoins the second electrode and is positioned at the substrate.

36. The solar cell of claim 18, wherein roughnesses of the first and second surfaces of the substrate are substantially equal to each other.

37. The solar cell of claim 18, wherein roughnesses of the first and second surfaces of the substrate are different from each other.
